(19) United States
(12) Patent Application Publication
(10) Pub. No.: US 2015/0130000 A1
(43) Pub. Date: May 14, 2015

(54) CHIP PACKAGE STRUCTURE AND METHOD FOR MANUFACTURING THE SAME

(71) Applicant: Teng Yen Lin, New Taipei City (TW)

(72) Inventor: Teng Yen Lin, New Taipei City (TW)

(21) Appl. No.: 14/077,258

(22) Filed: Nov. 12, 2013

(51) Int. Cl. H01L 31/0203; H01L 31/02; H01L 31/0232; H01L 31/18; H01L 31/0216

(52) U.S. Cl. CPC H01L 31/0203; H01L 31/1876; H01L 31/02165; H01L 31/02327; H01L 31/02005
USPC 257/432; 438/64

(57) ABSTRACT

A chip package structure includes a nanometer deposition layer and a chip having an electrical connection circuit, a photo sensing region and a plurality of electrical connection pads. The electrical connection pads and the photo sensing region are formed on the upper surface of the chip. The photo sensing region is covered with the nanometer deposition layer, which exposes the electrical connection pads. The nanometer deposition layer is used to provide electrical insulation, isolation and protection. The method for manufacturing the chip package structure includes cleaning the wafer with the chips, forming the nanometer deposition layer, and scribing the wafer to separate the chips. The present invention replaces the process of mold filling by directly forming the nanometer deposition layer so as to simplify the manufacturing steps, reduce the cost and facilitate the production, thereby shrinking the size of the chip package.

### BACKGROUND OF THE INVENTION

1. Field of the Invention

The present invention generally relates to a chip package structure and a method for manufacturing the same, and more specifically to a chip package structure having at least one of functional atomic deposition layer with a smaller and thinner size, and a method for manufacturing the same by replacing the process of mold filling with forming the deposition layer so as to simplify the manufacturing process, reduce the processing cost, facilitate the manufacturing process, increase the yield rate and additionally enhance the specific functions such as EMI (Electromagnetic Interference) suppression, redistribution layer (RDL), anti-reflection, anti-ultraviolet (UV) or IR (Infrared) cut.

2. The Prior Arts

As the advanced progress in the semiconductor technology, the function of the integrated circuits (ICs) becomes much powerful and more complicated. Especially, the circuit implemented on the chip is denser and the power consumption grows higher such that it is crucial to deal with the problems related to heat dissipation, EMI (electromagnetic interference), electrical conduction and signal integrity. Therefore, various new technologies have been successfully developed to package the chip with well sealing, water-proof and isolation, so as to make it easily applicable to most PCBs (printed circuit boards), other circuit boards and substrates for protection, enhancement of heat conduction and electrical performance, prevention of chip overheat and functional failure, and so on.

In the prior arts, some commonly used package technologies are DIP (Dual In-Line Package), QFP (Quad Flat Package), TSOP (Thin Small Outline Package), and BGA (Ball Grid Array). Generally, the traditional package needs the process of mold filling to encapsulate the IC with the package body made of the plastic material, which provides electrical isolation, heat dissipation and protection. Additionally, the package body is provided with connection pins to electrically connect the input/output ports of the IC so as to transfer electrical signals or electrical power. For example, the IC with few pins can be packaged by the DIP, which arranges the pins in two opposite sides of the package body. For the IC with more pins, the QFP with the pins provided at all four sides is a good selection. Practically, the QFP can support up to 256 pins. However, the BGA is a must for the IC with hundreds of pins because the tin solder balls are served as the physical pins with reduced size and configured at the bottom side of the substrate in a grid form.

For the ICs in the application field of mobile, handset or portable electronic devices such as cellar phones, the aspects of much lighter, thinner, shorter and smaller physical dimension have been strongly demanded to meet the requirement of powerful and complicated functions. Besides, the substrate of the BGA usually takes a larger area, and the size of the solder balls has a smallest limit such that the whole size of BGA package body can not be further reduced. As a result, the package industries are prompted to develop the CSP (Chip Scale Package) with even smaller package size. The present technology of the CSP can lightly reduce the traditional package with a final size just larger than the chip by 20%.

However, one of the shortcomings in the prior arts is that the traditional package technologies such as DIP, QFP, BGA and CSP need to perform the process of mold filling, which comprises first placing the chip in a mold, then filling the mold with the packaging material to encapsulate the chip, and finally heating up the packaging material to cure and form the package body with a vertical size (thickness) and a lateral size (area) strongly affected by the mold, the fluidity of the heated packaging material and the mechanical property of the package body. As a result, the traditional package body can not be further shrunk and fails to meet the requirements of the upcoming functional chips.

Furthermore, for the chip with transparent property such as photo image chip, the packaging needs additional processes to attach some pieces of glass element. For instance, one piece of glass element is attached by one additional process. It is possible to cause serious problems like contaminating the chip during the attaching process or shifting the whole structure, and potentially lead to functional failure.

Therefore, a new package structure with much lighter, thinner, shorter and smaller size and a method for manufacturing the same by forming the package body without the mold filling process are greatly needed to directly deposit one or more functional atomic layers to cover the chip so as to simplify the manufacturing flow, reduce the cost, facilitate the mass production and increase the yield, especially enhance the specific functions like EMI suppression, heat dissipation, redistribution layer, anti-reflection, anti-ultraviolet or IR cut, thereby overcoming the above problems in the prior arts.

### SUMMARY OF THE INVENTION

The primary objective of the present invention is to provide a chip package structure comprising a chip and a nanometer deposition layer. The chip has an electrical connection circuit, a photo sensing region and a plurality of electrical connection pads. The electrical connection pads and the photo sensing region are provided on the upper surface of the chip. The nanometer deposition layer covers the photo sensing region and exposes the electrical connection pads.

The photo sensing region has a function of photo sensing, and the electrical connection pads are connected to the electrical connection circuit used to connect external circuits or electrical components such as circuit boards or other ICs. Specifically, the photo sensing region is provided at the central region of the chip, and the electrical connection pads are provided on the outer border of the chip to enclose the photo sensing region.

The nanometer deposition layer has electrical insulation and transparency, and is made of a plastic material such as oxides, silicone, phenolic, polycarbonate, acrylic resin, polyimide, polytetrafluorethylen, BT (bismaleimide triazine) resin or epoxy resin.

Another objective of the present invention is to provide a chip package structure comprising a chip, a nanometer deposition layer, an electrical circuit layer and a plurality of connection bumps. Specifically, part of the lower surface of the electric circuit layer covers the outer border of the nanometer deposition layer, and the remaining part of the lower surface contacts the chip so as to electrically connect the electrical connection pads. The connection bumps are provided on the upper surface of the electrical connection circuit layer so as to connect the external circuits or electrical components. Therefore, the connection bumps are primarily intended to provide a larger connection area to extend the connection function of the electrical connection pads such that it is easier to solder or connect the external circuits or electrical components.

Another objective of the present invention is to provide a chip package structure comprising a chip, a nanometer deposition layer, an electrical circuit layer, a plurality of connection bumps and at least one electronic element. Specifically, the chip is a semiconductor IC having an electrical circuit and a plurality of electrical connection pads. The nanometer deposition layer is transparent or opaque. Additionally, the nanometer deposition layer covers part of the chip, but does not cover the electrical connection pads. The electrical circuit layer has a circuit pattern and covers the nanometer deposition layer and the chip so as to contact the electrical connection pads. The connection bumps are provided on the electrical circuit layer.

Therefore, the electrical connection pads are electrically connected to the connection bumps, and the electronic element like SMD including passive RC element is provided on the circuit pattern of the electrical circuit layer. As a result, the nanometer deposition layer is directly served as a substrate to support the electronic element, thereby simplifying the whole package structure.

Another objective of the present invention is to provide a method for manufacturing the chip package structure, which comprises cleaning a wafer having a plurality of chips, each chip having an electrical connection circuit, a photo sensing region and a plurality of electrical connection pads, forming a nanometer deposition layer on the chip to cover the photo sensing region and the surface of the chip without the electrical connection pads, and scribing the wafer to separate the chips so as to form a CSP (chip scale package) body having the chip and the nanometer deposition layer.

Another objective of the present invention is to provide a method for manufacturing the chip package structure, comprising: leaning a wafer having a plurality of chips, each chip having a photo sensing region and a plurality of electrical connection pads; forming a nanometer deposition layer on the chip to cover the photo sensing region; forming an electrical circuit layer covering the outer border of the chip; forming connection bumps on the electrical circuit layer; and scribing the wafer to separate the chips so as to form a CSP body having the chip, the nanometer deposition layer, the electrical circuit layer and the connection bumps.

Another objective of the present invention is to provide a method for manufacturing the chip package structure, comprising: cleaning a wafer having a plurality of chips, each chip having a photo sensing region and a plurality of electrical connection pads; forming a nanometer deposition layer on the chip to cover the photo sensing region; forming an electrical circuit layer covering the outer border of the chip and connection bumps on the electrical circuit layer; adhering or attaching the electronic element to the electrical circuit layer to connect the connection bumps; and scribing the wafer to separate the chips so as to form a CSP body having the chip, the nanometer deposition layer, the electrical circuit layer, the connection bumps and the electronic element.

One of the primary aspects of the present invention is to replace the traditional mold filling process with the nanometer deposition layer so as to reduce the package size and truly implement the CSP. Additionally, it is also possible to use masks and different nanometer deposition materials through several deposition processes to achieve the objectives of transparency, water-proof and EMI prevention for the package.

### BRIEF DESCRIPTION OF THE DRAWINGS

The present invention can be understood in more detail by reading the subsequent detailed description in conjunction with the examples and references made to the accompanying drawings, wherein:

FIG. 1 is a view illustrating a chip package structure according to a first embodiment of the present invention;

FIG. 2 is a top view of the chip package structure in FIG. 1;

FIG. 3 is an illustrative example of the chip package structure according to the present invention;

FIG. 4 is a view illustrating a chip package structure according to a second embodiment of the present invention;

FIG. 5 is a view illustrating a chip package structure according to a third embodiment of the present invention;

FIG. 6 is a flowchart illustrating a method of manufacturing the chip package structure according to the present invention;

FIG. 7 is a flowchart illustrating a method of manufacturing the chip package structure according to another embodiment of the present invention; and

FIG. 8 is a flowchart illustrating a method of manufacturing the chip package structure according to a yet embodiment of the present invention.

### DETAILED DESCRIPTION OF THE PREFERRED EMBODIMENTS

The present invention may be embodied in various forms and the details of the preferred embodiments of the present invention will be described in the subsequent content with reference to the accompanying drawings. The drawings (not to scale) show and depict only the preferred embodiments of the invention and shall not be considered as limitations to the scope of the present invention. Modifications of the shape of the present invention shall too be considered to be within the spirit of the present invention.

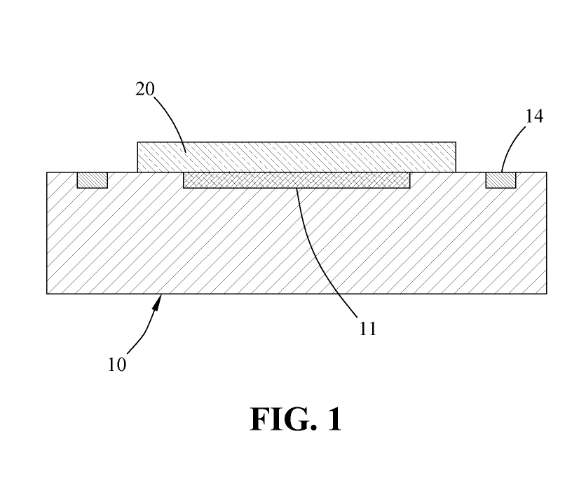

Please refer to FIG. 1 showing the chip package structure according to the first embodiment of the present invention. As shown in FIG. 1, the chip package structure of the first embodiment primarily comprises a chip 10 and a nanometer deposition layer 20. Specifically, the chip 10 such as a photo sensing chip has an electrical connection circuit (not shown), a photo sensing region 11 and a plurality of electrical connection pads 14, wherein the photo sensing region 11 and the electrical connection pads 14 are provided on the upper surface of the chip 10. The nanometer deposition layer 20 is formed by the semiconductor process to cover the surface of the photo sensing region 11. That is, the lateral size of the nanometer deposition layer 20 is larger than or equal to the lateral size of the photo sensing region 11. The purpose of covering is thus achieved.

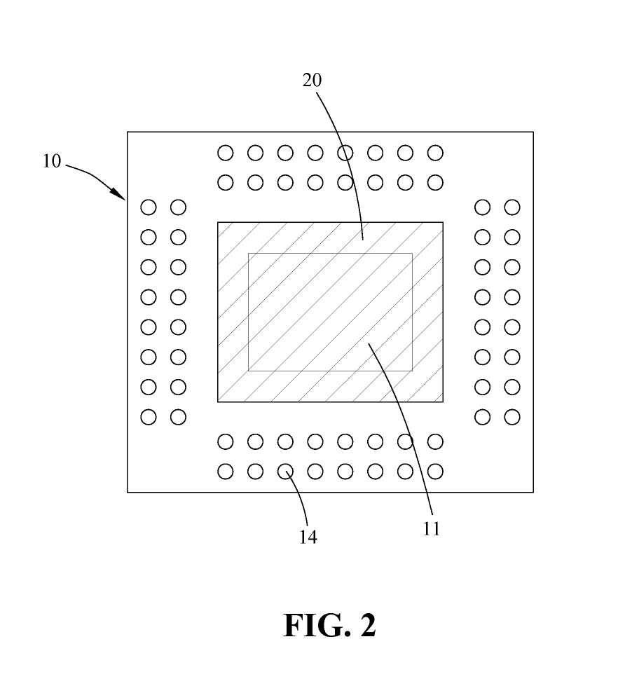

The photo sensing region 11 has a function of photo sensing. Additionally, the surface of the photo sensing region 11 is further provided with a plurality of micro lenses (not shown) to enhance the efficiency of photo sensing. The electrical connection pads 14 are electrically connected to the electrical connection circuit so as to provide electrical connection with external circuits or electrical elements, like circuit boards or other ICs. Please refer to FIG. 2 showing a top view of the chip package structure in FIG. 1. As shown in FIG. 2, the photo sensing region 11 is provided at the central region of the chip 10, and the electrical connection pads 14 are provided on the outer border of the chip 10, that is, the region enclosing the photo sensing region 11.

The nanometer deposition layer 20 possesses electrical insulation and transparency, and is made of a transparent and hydrophobic plastic material, such as oxides, silicone, phenolic, polycarbonate, acrylic resin, polyimide, polytetrafluorethylen, BT (bismaleimide triazine) resin or epoxy resin. Owing to the hydrophobic property of the nanometer deposition layer 20, it is possible to prevent a large amount of water from attaching to the nanometer deposition layer 20 and the water can be easily removed by blowing. Furthermore, the nanometer deposition layer 20 can protect the photo sensing region 11 from being contaminated by micro particles or dust. In particular, in case of the photo sensing region 11 provided with the micro lenses, it is easy to scratch the micro lenses, and the pollutant particles and dust possibly congregate at the gaps between the adjacent micro lenses and hard to remove. The nanometer deposition layer 20 of the present invention can solve these problems.

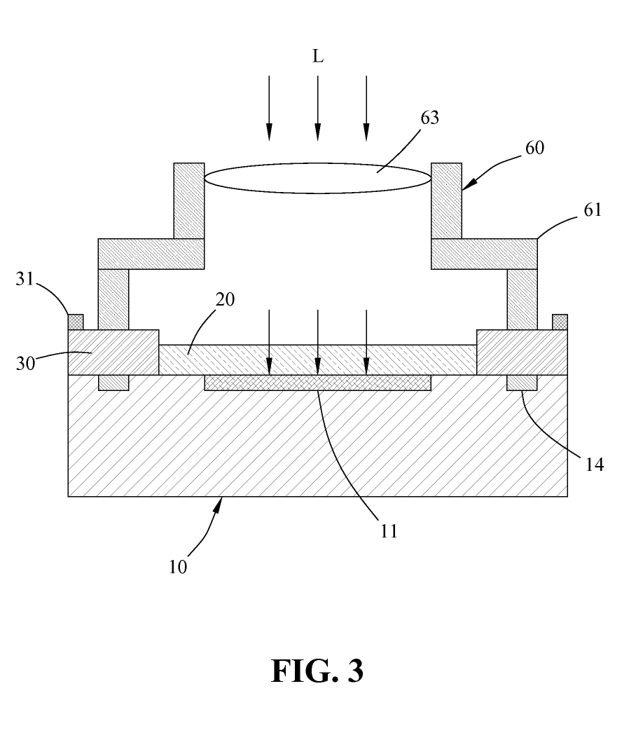

To more clearly explain the features of the present invention, please refer to FOG 3 showing an illustrative example of the chip package structure according to the present invention. As shown in FIG. 3, the circuit board 30 such as PCB (printed circuit board) can be provided on the upper surface of the chip 10 which is not covered by the nanometer deposition layer 20 so as to contact the electrical connection pads 14 and expose the photo sensing region 11 of the chip 10. Alternatively, the electrical connection pads 14 are connected to the bottom of the circuit board 30 via soldering traces. The positive surface of the circuit board has a plurality of connection soldering points 31, which is preferably provided on the outer border of the circuit board 30.

Additionally, the lens socket 60 is provided on the circuit board 30, and the empty chamber is formed between the chip 10 and the lens socket 60. The lens socket 60 comprises a covering body 61 and a plurality of lens 63 which are combined together. The lens 63 are aligned to the photo sensing region 11 of the chip 10, and the covering body 61 is fixed to the circuit board 30 by a fixing resin. Therefore, the external incident light L can penetrate the lens 31 to the nanometer deposition layer 20, and further penetrate the nanometer deposition layer 20 to the photo sensing region 11.

In addition to the protection of isolation, the nanometer deposition layer 20 has low reflectivity and can be used as the antireflection layer to reduce or eliminate the effect of reflection such that the light incident onto the nanometer deposition layer 20 can be received as much as possibly by the photo sensing region 11 under the nanometer deposition layer 20, thereby increasing the whole efficiency of photo sensing. Preferably, the nanometer deposition layer 20 as the antireflection layer may have a thickness between 120 and 260 nm. The traditional antireflection films or antireflection sheets are thus not needed and the lens 63 does not have to coat an antireflection film such that the manufacturing process is simplified, the coast is reduced and the quality of the final product is greatly improved.

However, it should be noted that the example illustrated in FIG. 3 is only used to clearly describe the key features of the present invention, and not intended to limit the scope of the present invention. That is, the chip package structure of the present invention is substantially applicable to other application fields.

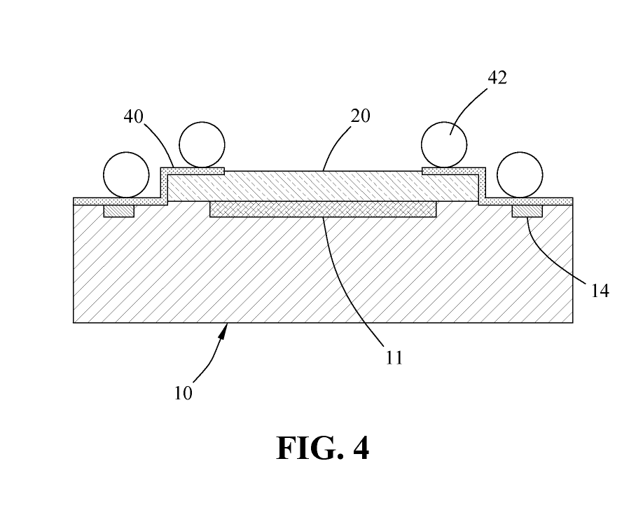

Further refer to FIG. 4 showing the chip package structure according to the second embodiment of the present invention. The chip package structure of the second embodiment comprises a chip 10, a nanometer deposition layer 20, an electrical circuit layer 40 and a plurality of connection bumps 42. As for the technical aspects, the chip 10 and the nanometer deposition layer 20 of the present embodiment are similar to those of the first embodiment in FIG. 1. That is, the chip 10 such as a photo sensing chip has an electrical connection circuit (not shown), a photo sensing region 11 and a plurality of electrical connection pads 14, and the nanometer deposition layer 20 covers the surface of the photo sensing region 11. Thus, the detailed description is omitted.

The electrical circuit layer 40 of the second embodiment has a metal conductive layer comprising the circuit pattern (not shown), and part of the lower surface of the electrical circuit layer 40 covers the outer border of the nanometer deposition layer 20. Besides, the other remaining part of the lower surface contacts the chip 10 and is electrically connected to the electrical connection pads 14. The connection bumps 42 are provided on the upper surface of the electrical circuit layer 40 to connect the external circuits or the electrical elements such that the connection bumps 42 is primarily provided to extend the connection function of the electrical connection pads 14. That is, it is not necessary for the external circuits or the electrical elements to directly connect the electrical connection pads 14, but the external circuits or the electrical elements can be electrically connected to the electrical connection pads 14 through the connection bumps 42.

In general, the maximum size of the electrical connection pad 14 is only 80×80 um because the outer border of the chip 10 is limited. For some electrical elements, their electrical functions will greatly deteriorate if the soldering area is insufficient. According to the present invention, the connection bumps 42 are formed on the electrical circuit layer 40 such that the size of the connection bump 42 is up to 120×120 μm, or even 150×150 μm, thereby improving the yield rate of the subsequent solder process. Similar to the first embodiment, the chip package structure of the second embodiment can be used to connect the lens socket so as to form the photo sensing module. Thus, the whole structure is improved and the efficiency of photo sensing is increased.

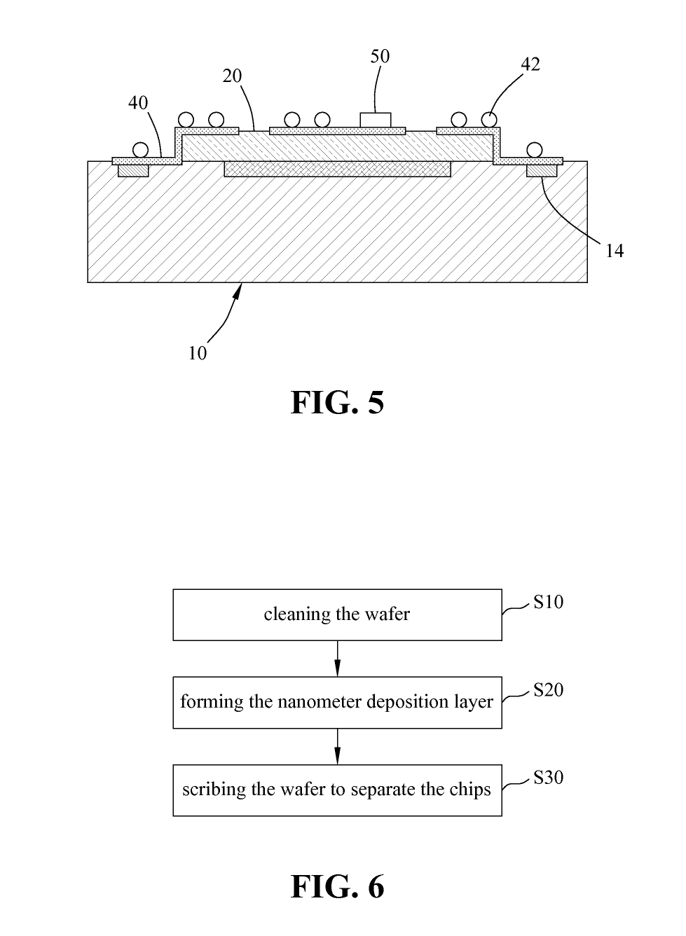

Further refer to FIG. 5 showing the chip package structure according to the third embodiment of the present invention. As shown in FIG. 5, the chip package structure of the third embodiment comprises a chip 10, a nanometer deposition layer 20, an electrical circuit layer 40, a plurality of connection bumps 42 and at least one electronic element 50. The chip 10 is a semiconductor IC, and the nanometer deposition layer 20 is transparent or opaque. Specifically, the chip 10 has an electrical connection circuit (not shown) and a plurality of electrical connection pad 14. The nanometer deposition layer 20 covers part of the surface of the chip 10, and exposes the electrical connection pad 14. The electrical circuit layer 40 has an electrical pattern and covers the nanometer deposition layer 20 and the chip 10 so as to contact the electrical connection pad 14. The connection bumps 42 are provided on the electrical circuit layer 40 such that the electrical connection pad 14 and the connection bumps 42 are electrically connected. Besides, the electronic element 50 such as SMD (surface mounted device) including a passive RC element is provided on the electrical pattern of the electrical circuit layer 40.

Therefore, the nanometer deposition layer 20 primarily provides the chip 10 with isolation, protection and electrical insulation to prevent the chip 10 from being contaminated by micro particles or pollutant dust. The technical aspect of the nanometer deposition layer 20 is described in the first embodiment, and thus omitted herein. The electronic element 50 in the actual application is directly soldered to the electrical circuit layer 40 on the nanometer deposition layer 20, thereby greatly simplifying the whole structure and further reducing the package size.

Moreover, the present invention also provides a method for manufacturing the chip package structure. Refer to FIG. 6 showing the flowchart for the method according to the present invention. As shown in FIG. 6, the method of the present invention starts at the step S10 to clean a wafer having a plurality of chips. Each chip has an electrical connection circuit, a photo sensing region and a plurality of electrical connection pads. The electrical connection pads and the photo sensing region are provided on the upper surface of the chip.

Next, in the step S20, a nanometer deposition layer is formed on each chip to cover the photo sensing region and expose the electrical connection pads. The nanometer deposition layer is made of oxides, silicone, phenolic, polycarbonate, acrylic resin, polyimide, polytetrafluorethylen, BT resin or epoxy resin. Specifically, the nanometer deposition layer is formed through a CVD (chemical vapor deposition) process or a process of spin coating and curing. Especially, the lower processing temperature like 50˜70° C. is feasible for the process such that the photoelectrical property of the photo sensing region is maintained and the function electrical insulation is provided.

Finally, the scribing step S30 is performed to scribe the wafer to separate the chips.

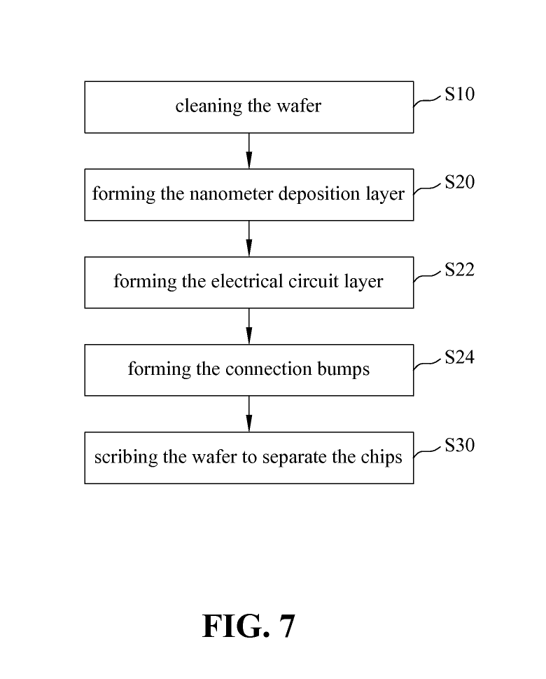

Additionally, refer to FIG. 7 showing the flowchart of the method e according to another embodiment of the present invention. As shown in FIG. 7, the method of the present embodiment comprises the sequential steps S10, S20, S22, S24 and S30. The steps S10, S20 and S30 are the same as the method in FIG. 6, so the detail description is omitted. The primary difference is that the method of the present embodiment additionally comprises the steps S22 and S24. More specifically, the step S22 is performed after the step S20 to form an electrical circuit layer on the nanometer deposition layer and the chip to cover the outer border of the nanometer deposition layer and contact the electrical connection pads so as to achieve the circuit layout. In the step S24, a plurality of connection bumps is formed on the electrical circuit layer for connecting external circuits or electrical components.

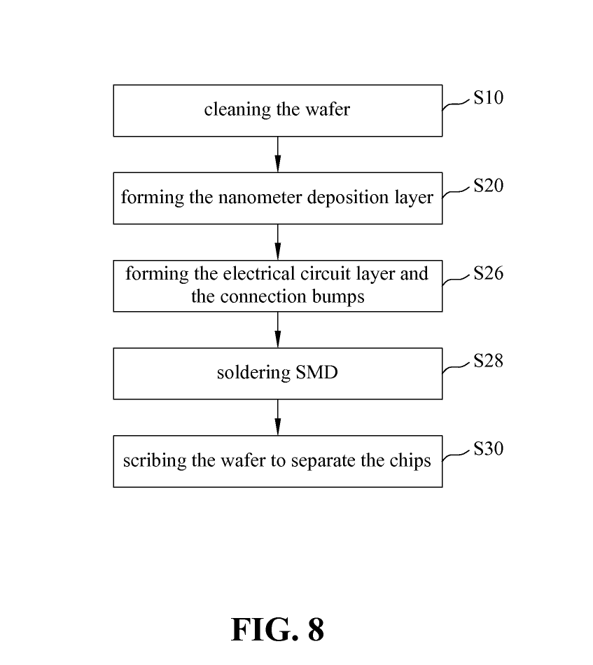

Furthermore, refer to FIG. 8 showing the flowchart of the method according to a yet embodiment of the present invention. The method of the yet embodiment comprises the sequential steps S10, S20, S26, S28 and S30, wherein the steps S10, S20 and S30 are the same as the method in FIG. 6. However, the chip of the present embodiment does not include the photo sensing chip. That is, the chip does not have the photo sensing region. Other technical features of the present embodiment are the same as the method in FIG. 6 and the related description is thus omitted.

The primary difference is that the method in FIG. 8 additionally comprises the steps S26 and S28. Specifically, the step S26 is performed to form an electrical circuit layer and a plurality of connection bumps. The electrical circuit layer covers the outer border of the nanometer deposition layer and contacts the electrical connection pads. The connection bumps are formed on the electrical circuit layer. Then, in the step S28, the Surface Mount Technology (SMT) is used to connect or solder the electronic element like the SMD to the connection bumps so as to form the desired circuit.

From the above description, one feature of the present invention is that the nanometer deposition layer is formed to replace the process of mold filling, and directly encapsulate the chip so as to provide electrical insulation, isolation and protection. The package size is greatly reduced to truly implement the CSP, only hundreds nanometer (like 250 nm) larger than the chip. In particular, the thickness of the package is only the thickness of the chip plus the thickness of the nanometer deposition layer, thereby achieving the properties including transparency, water-proof and EMI suppression. Therefore, the present invention has the advantages of simpler processing, higher yield and lower cost, thereby fulfilling the purpose of industrial application.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A chip package structure, comprising:
a chip having an electrical connection circuit, a photo sensing region and a plurality of electrical connection pads, the electrical connection pads and the photo sensing region provided on an upper surface of the chip, the photo sensing region exhibiting a photo sensing function, the electrical connection pads connected to the electrical connection circuit, wherein the electrical connection pads are used to connect external circuits or electrical components; and
a nanometer deposition layer with electrical insulation and transparency covering the photo sensing region and exposing the electrical connection pads, wherein the nanometer deposition layer is made of a transparent and hydrophobic plastic material.

2. The chip package structure as claimed in claim 1, wherein the photo sensing region is provided at a central region of the chip, the electrical connection pads are provided on an outer border of the chip, and the plastic material comprises oxides, silicone, phenolic, polycarbonate, acrylic resin, polyimide, polytetrafluorethylen, BT (bismaleimide triazine) resin or epoxy resin.

3. The chip package structure as claimed in claim 1, wherein the photo sensing region has a surface provided with a plurality of micro lenses, and the nanometer deposition layer with low reflectivity serves as an antireflection layer and has a thickness between 120 and 260 nm.

4. The chip package structure as claimed in claim 1, further comprising:
an electrical circuit layer served as a metal conductive layer with a circuit pattern, part of a lower surface of the electric circuit layer covering an outer border of the nanometer deposition layer, a remaining part of the lower surface of the electric circuit layer contacting the chip and electrically connected to the electrical connection pads; and
a plurality of connection bumps provided on an upper surface of the electrical circuit layer for connecting the external circuits or the electrical components.

5. A chip package structure, comprising:
a chip having an electrical connection circuit and a plurality of electrical connection pads, the electrical connection pads provided on an upper surface of the chip and used to connect external circuits or electrical components; and
a nanometer deposition layer transparent or opaque, covering part of the chip and exposing the electrical connection pads, wherein the nanometer deposition layer has electrical insulation and is made of a hydrophobic plastic material;
an electrical circuit layer served as a metal conductive layer with a circuit pattern, wherein part of a lower surface of the electric circuit layer covers an outer border of the nanometer deposition layer, and a remaining part of the lower surface of the electric circuit layer contacts the chip so as to electrically connect the electrical connection pads;
a plurality of connection bumps provided on an upper surface of the electrical circuit layer for connecting the external circuits or the electrical components; and
at least one electronic element implemented by a SMD (surface mounted device) and provided on the circuit pattern of the electrical circuit layer.

6. The chip package structure as claimed in claim 5, wherein the plastic material comprises oxides, silicone, phenolic, polycarbonate, acrylic resin, polyimide, polytetrafluorethylen, BT resin or epoxy resin.

7. A method for manufacturing a chip package structure, comprising:
cleaning a wafer having a plurality of chips, each chip having an electrical connection circuit, a photo sensing region and a plurality of electrical connection pads, wherein the electrical connection pads and the photo sensing region are provided on an upper surface of the chip;
forming a nanometer deposition layer on the chip by employing a CVD (chemical vapor deposition) process or a process of spin coating and curing so as to cover the photo sensing region and expose the electrical connection pads, wherein the nanometer deposition layer has electrical insulation and transparency, and the nanometer deposition layer is made of a plastic material; and
scribing the wafer to separate the chips.

8. The method as claimed in claim 7, wherein the chip is implemented by an IC, the electrical connection pads are provided on an upper surface of the chip, and the plastic material comprises oxides, silicone, phenolic, polycarbonate, acrylic resin, polyimide, polytetrafluorethylen, BT resin or epoxy resin.

9. The method as claimed in claim 7, further comprising an additional step after the step of forming the nanometer deposition layer, wherein the additional step comprises:
forming an electrical circuit layer on the nanometer deposition layer and the chip to cover the outer border of the nanometer deposition layer and contact the electrical connection pads; and
forming connection bumps on the electrical circuit layer for connecting external circuits or electrical components.

10. A method for manufacturing a chip package structure, comprising:
cleaning a wafer having a plurality of chips, each chip having an electrical connection circuit and a plurality of electrical connection pads, wherein the electrical connection pads are provided on an upper surface of the chip;
forming a nanometer deposition layer on the chip by employing a CVD process or a process of spin coating and curing, wherein the electrical connection pads are exposed, the nanometer deposition layer has electrical insulation, and the nanometer deposition layer is made of a plastic material; and scribing the wafer to separate the chips.

11. The method as claimed in claim 10, wherein the chip is a photo sensing chip with a photo sensing region at a central region of the chip, the electrical connection pads are provided on an outer border of the chip, and the plastic material comprises oxides, silicone, phenolic, polycarbonate, acrylic resin, polyimide, polytetrafluorethylen, BT resin or epoxy resin.

12. The method as claimed in claim 10, further comprising an additional step after the step of forming the nanometer deposition layer, wherein the additional step comprises:
forming an electrical circuit layer on the nanometer deposition layer and connection bumps on the electrical circuit layer, the electrical circuit layer covering the outer border of the nanometer deposition layer and contacting the electrical connection pads; and
connecting or soldering at least one electronic element to the connection bumps by soldering through SMT (surface mount technology), the electronic element comprising an SMD.
